(19) United States
(12) Patent Application Publication
(10) Pub. No.: US 2010/0083998 A1
(43) Pub. Date: Apr. 8, 2010

(54) Solar Cell Receiver with a Glass Lid

(75) Inventors: Steve Seel, Albuquerque, NM (US); Robert Meck, Placitas, NM (US); James Foresi, Albuquerque, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/246,295

(22) Filed: Oct. 6, 2008

(51) Int. Cl. H01L 31/042

(52) U.S. Cl. 136/244

(57) ABSTRACT

A solar cell receiver for converting solar energy to electricity including a substrate, a III-V compound semiconductor multi-junction solar cell mounted on the substrate, a diode mounted on the substrate, including a body, an anode contact and a cathode contact, the diode coupled in parallel with the solar cell, output terminals mounted on the substrate and coupled to the solar cell and the diode for handling more than 10 watts of power, and at least one spacer and a transparent lid thereover configured to cover and protect the solar cell.

### FIELD OF THE INVENTION

The present invention relates to a solar cell receiver having at least one spacer and a transparent lid configured to cover the solar cell and to protect it.

### BACKGROUND OF THE INVENTION

Typically, a plurality of solar cells is disposed in an array or panel, and a solar energy system typically includes a plurality of such panels. The solar cells in each panel are usually connected in series, and the panels in a given system are also connected in series, with each panel having numerous solar cells. The solar cells in each panel could, alternatively, be arranged in parallel.

Historically, solar power, both in space and terrestrial, has been predominantly provided by silicon solar cells. In the past several years, however, high-volume manufacturing of high-efficiency multi-junction solar cells has enabled the use of this alternative technology for power generation. Some current multi-junction cells have energy efficiencies that exceed 27%, whereas silicon technologies generally reach only about 17% efficiency.

Generally speaking, the multi-junction cells are of n-on-p polarity and are composed of InGaP/(In)GaAs/GaAs III-V compounds. The III-V compound semiconductor multi-junction solar cell layers can be grown via metal-organic chemical vapor deposition, MOCVD, on Ge substrates. The epi-wafers can be processed into complete devices through automated robotic photolithography, metallization, chemical cleaning and etching, antireflection (AR) coating, dicing, and testing processes. The n-and-p contact metallization is typically comprised of predominately Ag with a thin Au cap layer to protect the Ag from oxidation. The AR coating is generally a dual-layer TiOₓ/Al₂Oₓ dielectric stack, whose spectral reflectivity characteristics are designated to minimize reflection at the cover glass-interconnected-cell, CIC, or the solar cell assembly, SCA, level, as well as, maximizing the end-of-life, EOL, performance of the cells.

In some multi-junction cells, the middle cell is an InGaAs cell as opposed to a GaAs cell. The indium concentration may be in the range of about 1.5% for the InGaAs middle cell. In some implementations, such an arrangements exhibits increased efficiency.

Regardless of the type of cell used, a known problem with solar energy systems is that individual solar cells can become damaged or shadowed by an obstruction. For example, damage can occur as a result of exposure of a solar cell to harsh environmental conditions. The current-carrying capacity of a panel having one or more damaged or shadowed solar cells is reduced, and the output from other panels in series with that panel reverse biases the damaged or shadowed cells. The voltage across the damaged or shadowed cells thus increases in a reverse polarity until the full output voltage of all of the panels in the series is applied to the damaged or shadowed cells in the panel concerned. This causes the damaged or shadowed cells to breakdown.

As a typical solar cell system has thousands of solar cells, its voltage output is normally in the range of hundreds of volts, and its current output is in the range of tens of amperes. At these output power levels, if the solar cell terminals are not protected, uncontrollable electric discharge in the form of sparks tend to occur, and this can cause damage to the solar cells and the entire system.

Typically, each solar cell is coupled with a diode connected between its positive and negative terminals. The provision of the diodes, typically Schottky bypass diodes, does go some way to protecting the solar cells against the uncontrollable electric discharges mentioned above, as well as preventing cell damage during shadowing.

Another disadvantage of known solar cells is that they are not protected, covered, or isolated mechanically, in order that the possible dirtiness accumulated on the system, or any other agent, may not produce any damage to the solar cell.

### BRIEF DESCRIPTION OF THE INVENTION

The invention relates to an apparatus for converting solar energy to electricity. Said apparatus comprises a substrate and a III-V compound semiconductor multi-junction solar cell for converting solar cell into electricity. The solar cell is mounted on the substrate and comprises a first contact coupled to a p-polarity side of the cell and a second contact coupled to an n-polarity side of the cell. The apparatus also comprises a diode, on the substrate, comprising a body, an anode contact and a cathode contact. The diode is coupled in parallel with the first and second contacts of the solar cell such that the anode contact of the diode is coupled to the first contact and the cathode contact of the diode is coupled to the second contact. Output terminals, comprised on the apparatus, are mounted on the substrate and coupled to the solar cell and the diode for handling more than 10 watts of power.

The apparatus of the present invention additionally comprises at least one spacer and a lid configured to cover and protect said apparatus. The lid may be mounted on the spacers, therefore, the inclusion of said lid does not affect the solar cell since it does not interfere with any of the components previously listed. The lid acts as a protection of the solar cell, so that any possible dirt, obstruction or undesired element may not damage the solar cell.

The spacer or spacers can be any surface mount component of appropriate thickness. For example, resistors are inexpensive surface mount components that can be handled by automatic equipment. Therefore, the cost of the solar cell is not significantly impacted with the advantage of improved robustness to damage. The resistors are not connected to the electrical circuit and act purely as mechanical standoffs. The value of the resistors is the easiness with that the automatic equipment handles them. Other possible surface mount component that could be used are for instance plastic strips, but, given to the fact that the automatic equipment is not prepared to handle said plastic strips, and that the automatic equipment will need additional modifications, which will imply an extra cost, resistors represent the cheapest solution for the spacers. They are themselves cheap and the equipment does not need additional amendments. Nevertheless, any other solution that may act as a mechanical standoff is valid, as, for instance, a protrusion on the substrate. Other possible alternative is a ceramic ring-frame. The ceramic-ring would act as the resistors, or any other surface mount component, and support the lid.

Preferably, the lid is a glass lid. Such lid will not substantially reduce the light transmission to the solar cell and will not reduce the performance of the solar cell. Other solutions are possible, as far as they do not reduce the output of the solar cell.

In some implementations, the diode is operable to be forward-biased in instances when the solar cell is not generating above a threshold voltage.

In some implementations, the solar cell comprises at least one layer comprising InGaP, InGaAs or GaAs.

In some implementations, the solar cell comprises an anti-reflective coating.

The apparatus may comprise a silicone material between the solar cell and the lid. This material improves transmission through the stack and, therefore, the efficiency of the solar cell. Alternatively, an air layer may occupy the space between the solar cell and the lid. In this case, the solar cell has higher transmission losses, but the concern of epoxy degradation over time is eliminated.

### BRIEF DESCRIPTION OF THE DRAWINGS

To complement the description being made and for the purpose of aiding to better understand the features of the invention according to a preferred practical embodiment thereof, a drawing is attached as an integral part of said description, showing the following with an illustrative and non-limiting character:

FIG. 1 shows a perspective view of the apparatus for converting solar energy to electricity of the present invention.

### PREFERRED EMBODIMENT OF THE INVENTION

In view of the discussed figure, a possible embodiment of an apparatus for converting solar energy to electricity according to the invention is disclosed.

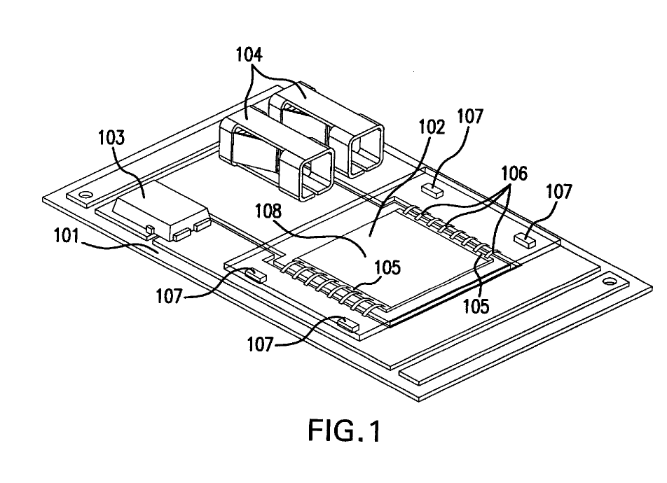

FIG. 1 shows a ceramic substrate 101 where a solar cell 102, a bypass diode 103 and output terminals 104 are mounted.

The solar cell 102 may be made from, e.g., silicon, cadmium, telluride, CIGS, CIS, gallium arsenide, light absorbing dyes, or organic semiconductors. In the implementation described herein, a triple-junction III-V compound semiconductor solar cell 102 is employed, but other types of solar cells could be used depending on the application.

The solar cell 102 is a triple-junction III-V compound semiconductor solar cell which is constituted by a top cell, a middle cell and a bottom cell arranged in series.

A diode 103 is connected in parallel with the triple-junction solar cell 102. In some implementations, the diode 103 is a semiconductor device such as a Schottky bypass diode or an epitaxially grown p-n junction. External connection terminals 104, or output terminals 104, are mounted on the substrate 101 which is made of insulation material.

The solar cell 102 is electrically connected to the diode 103. The upper surface of the solar cell 102 comprises a contact area 105 that, in this implementation, occupies two sides of the solar cell 102. However, the contact area 105 may touch only one, three or all the perimeter of the solar cell 102. In some implementations, the contact area 105 is made as small as possible to maximize the area that converts solar energy into electricity, while still allowing electrical connection. The contact area 105 may be formed of a variety of conductive materials, e.g., copper, silver, and/or gold-coated silver.

An anti-reflective coating may be disposed on the solar cell 102. The antireflective coating may be a multilayer antireflective coating providing low reflectance over a certain wavelength range, e.g., 0.3 to 1.8 μm. An example of an anti-reflective coating is a dual-layer TiOₓ/Al₂Oₓ dielectric stack.

The contact area 105 is coupled to a conductor trace that is disposed on the substrate 101. In this implementation, the contact is coupled to the conductor trace by a plurality of wire bonds 106. The number of wire bonds 106 can be related, among other things to the amount of current generated by the solar cell 102. The solar cell 102 and the diode 103 are connected in parallel.

The solar cell 102 includes in this implementation two pairs of spacers 107. Each pair is situated on the same side of each of the contact areas 105. As it can be shown in the figure, the spacers 107 will be placed near the end of the substrate 101, being the wire bonds 106, the contact areas 105 and the solar cell 102 placed between the two pairs of spacers 107.

The spacers 107 are resistors 107. Automatic equipment may place the resistors 107 on the right places with no modification of said equipment. The resistors 107, however, are not connected to anything, being their role to act as a support of the lid 108 depicted on the figure on top of the resistors 107, covering and protecting said resistors 107 and the solar cell 102. Being the solar cell 102 covered by said lid 108, the lid 108 must be built on a material that does not block or attenuate the solar energy. Glass is the material chosen for this implementation, however, other materials can be used.

In view of this description and the drawing, a person skilled in the art will understand that the embodiment of the invention that has been described can be combined in many ways within the object of the invention. The invention has been described according to a preferred embodiment thereof, but it will be evident for a person skilled in the art that many variations can be introduced in said preferred embodiments without exceeding the scope of the claimed invention.

1. A solar cell receiver apparatus for converting solar energy to electricity comprising:
a substrate,
a III-V compound semiconductor multi-junction solar cell for converting solar energy into electricity, the solar cell mounted on the substrate and comprising a first contact coupled to a p-polarity side of the cell and a second contact coupled to an n-polarity side of the cell,
a diode, disposed on the substrate, including a body, an anode contact and a cathode contact, the diode coupled in parallel with the first and second contacts of the solar cell such that the anode contact of the diode is coupled to the first contact and the cathode contact of the diode is coupled to the second contact, and
output terminals mounted on the substrate and coupled to the solar cell and the diode for handling more than 10 watts of power,
wherein
the apparatus additionally comprises at least one spacer and a lid, configured so that the lid covers and protects said solar cell.

2. The apparatus of claim 1, wherein the spacer is a surface mount component of predetermined thickness.

3. The apparatus of claim 2, wherein the surface mount component is not electrically connected to any other component on the apparatus.

4. The apparatus of claim 1, wherein the spacer is a ring-frame of appropriate thickness.

5. The apparatus of claim 1, wherein the lid is a glass lid.

6. The apparatus of claim 2, wherein the lid is mounted on the spacers.

7. The apparatus of claim 4, wherein the lid is mounted on the ring frame.

8. The apparatus of claim 1, wherein the diode is operable to be forward-biased in instances when the solar cell is not generating above a threshold voltage.

9. The apparatus of claim 1, wherein the solar cell comprises layers including InGaP, InGaAs and GaAs.

10. The apparatus of claim 1, wherein the solar cell comprises an anti-reflective coating.

11. The apparatus of claim 1, wherein a silicone material is disposed between the solar cell and the lid.

12. The apparatus of claim 1, wherein an air layer is disposed between the solar cell and the lid.
